(19) United States
(12) Patent Application Publication
(10) Pub. No.: US 2004/0212091 A1
(43) Pub. Date: Oct. 28, 2004

(54) Semiconductor device substrate

(75) Inventors: Yoji Asahi, Nagano-shi (JP); Yukiji Ootsuka, Nagano-shi (JP); Keisuke Ueda, Nagano-shi (JP)

Correspondence Address: STAAS & HALSEY LLP, SUITE 700, 1201 NEW YORK AVENUE, N.W., WASHINGTON, DC, 20005, US

(73) Assignee: SHINKO ELECTRIC INDUSTRIES CO., LTD., Nagano (JP)

(21) Appl. No.: 10/827,318

(22) Filed: Apr. 20, 2004

(30) Foreign Application Priority Data
Apr. 25, 2003 (JP) 2003-122058(PAT.

(51) Int. Cl. H01L 23/48

(52) U.S. Cl. 257/758

(57) ABSTRACT

A semiconductor device substrate comprised of a core substrate on both surfaces or on one surface of which interconnect patterns are formed via resin layers, wherein the core substrate is formed by a material having a heat expansion coefficient close to a semiconductor chip, that is, a heat expansion coefficient closer to a semiconductor chip than the resin layers and the interconnect patterns inside the substrate, a resin layer forming an outermost layer of the substrate is formed using a material having a higher strength and/or a higher elongation than the resin material used for the inner resin layers in the substrate, and thereby cracking, deformation, and other problems arising in the substrate due to the thermal stress occurring between the core substrate and the resin layers in the substrate and interconnect patterns being prevented.

### BACKGROUND OF THE INVENTION

1. Field of the Invention

The present invention relates to a semiconductor device substrate, more particularly relates to a semiconductor device substrate comprised of a core substrate on both surfaces or on one surface of which interconnect patterns are formed through a resin layer and having a core substrate formed from a material having a heat expansion coefficient close to that of a semiconductor chip, that is, a heat expansion coefficient closer to that of a semiconductor chip than the resin layers and the interconnect patterns inside the substrate.

2. Description of the Related Art

Along with the increasingly higher speeds of semiconductor chips mounted on semiconductor devices, recently reduction of the dielectric constant of the semiconductor chips themselves has become sought. To reduce the dielectric constant of a semiconductor device, in recent semiconductor devices the practice has been to make the insulating layer forming the semiconductor chip porous to lower the dielectric constant. A semiconductor chip formed with a porous insulating layer in this way falls in strength compared with a conventional semiconductor chip, so there is then the problem that when mounting that semiconductor chip on a substrate, it ends up being damaged by the thermal stress caused by the difference in heat expansion coefficients between the semiconductor chip and the substrate. See for example Japanese Unexamined Patent Publication (Kokai) No. 2001-274556 and Japanese Unexamined Patent Publication (Kokai) No. 10-335835.

Therefore, attempts have been made to reduce the thermal stress produced between the substrate and a semiconductor chip by bringing the heat expansion coefficient of the substrate mounting the semiconductor chip close to the heat expansion coefficient of the semiconductor chip. There are various types of semiconductor device substrates, but for example in the case of a semiconductor device substrate comprised of a core substrate on both surfaces of which interconnect patterns are formed through resin layers, it may be considered to use as the core substrate one made of an iron-nickel alloy etc. having a heat expansion coefficient close to the heat expansion coefficient of the semiconductor chip.

If using a material with a smaller heat expansion coefficient than the materials used for conventional semiconductor device substrates for the core substrate, however, there is the problem that the difference in the heat expansion coefficients between the core substrate and the resin layers formed on its surfaces or the difference in the heat expansion coefficients with the interconnect patterns formed on the resin layers will cause a large thermal stress between the core substrate and the resin layers or interconnect patterns and result in the substrate cracking or the interconnect patterns breaking.

Copper is preferably used for the interconnect patterns. The heat expansion coefficient of copper is far larger than the heat expansion coefficient of a semiconductor chip comprised of silicon, so if bringing the core substrate close to the semiconductor chip in heat expansion coefficient, occurrence of a difference in heat expansion coefficients between the core substrate and the interconnect patterns cannot be avoided. In point of fact, if using a material close in heat expansion coefficient to a semiconductor chip for the core substrate, using a resin material (epoxy resin) used in a conventional semiconductor device substrate for the resin layer to prepare the semiconductor device substrate, and testing the reliability by a thermal shock test etc., the resin layers and the interconnect patterns will end up cracking.

### SUMMARY OF THE INVENTION

An object of the present invention is to provide a semiconductor device substrate comprised of a core substrate on both surfaces of which interconnect patterns are formed via resin layers and having a core substrate formed from a material having a heat expansion coefficient close to a semiconductor chip, that is, a heat expansion coefficient closer to a semiconductor chip than the resin layers and the interconnect patterns inside the substrate, which solves the problem of the difference in heat expansion coefficients between the core substrate and resin layers or interconnect patterns causing the resin layers or interconnect patterns to crack and enabling reliable mounting of even a semiconductor chip lowered in dielectric constant and consequently reduced in strength.

To attain the above object, the present invention provides a semiconductor device substrate comprised of a core substrate on at least one surface of which interconnect patterns are formed via resin layers, wherein the core substrate is formed by a material having a heat expansion coefficient closer to a semiconductor chip than the resin layers and interconnect patterns inside the substrate, and a resin layer forming an outermost layer of the substrate is formed using a material having at least one of a higher strength and a higher elongation than a resin material used for inner resin layers in the substrate, thereby easing thermal stress between the core substrate and the resin layers in the substrate and interconnect patterns, so that cracking, deformation, and other problems arising in the substrate due to the thermal stress occurring between the core substrate and the resin layers in the substrate and interconnect patterns are prevented.

Preferably, a resin layer under a resin layer forming an outermost layer of the substrate is made of a resin material having at least one of a higher strength and higher elongation than the resin material of a resin layer used further inside the substrate. The resin material having at least one of a higher strength and higher elongation may be a resin material having a fracture strength of at least 90 MPa and elongation of at least 10%.

### BRIEF DESCRIPTION OF THE DRAWINGS

These and other objects and features of the present invention will become clearer from the following description of the preferred embodiments given with reference to the attached drawings, wherein:

FIG. 1 is a cross-sectional view of the configuration of a semiconductor device substrate according to an embodiment of the present invention;

FIG. 2 is a cross-sectional view of the configuration of a semiconductor device substrate according to another embodiment of the present invention;

FIG. 3 is a cross-sectional view of the configuration of a semiconductor device substrate according to still another embodiment of the present invention; and

FIG. 4 is a graph of the relationship of the stress at the substrate surface and the fracture strength for resin materials with different fracture strengths.

### DESCRIPTION OF THE PREFERRED EMBODIMENTS

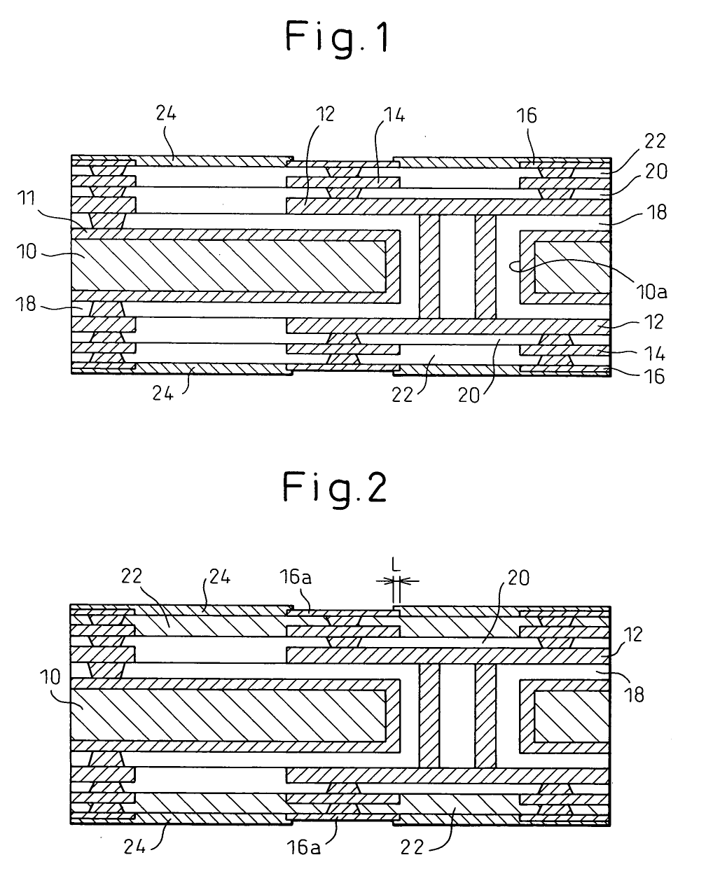

Preferred embodiments of the present invention will be described in detail below while referring to the attached figures. FIG. 1 is a cross-sectional view of the configuration of a semiconductor device substrate according to a first embodiment of the present invention. In the figure, 10 indicates a core substrate comprised of an iron-nickel alloy, 10a a through hole passing through the core substrate in the thickness direction, and 11 a copper plating layer provided for improving the bonding between the core substrate 10 and a resin layer. Reference numeral 12 indicates first layer interconnect patterns, 14 indicates second layer interconnect patterns, and 16 indicates third layer interconnect patterns. The interconnect patterns 12, 14, and 16 provided as the first layer, second layer, and third layer on the two surfaces of the core substrate 10 are arranged completely symmetrically at the two surfaces of the core substrate 10 in the present embodiment.

Reference numeral 18 indicates a resin layer for electrically insulating the core substrate 10 and the first layer interconnect patterns 12, 20 indicates a resin layer for filling the through hole 10a and electrically insulating between the first layer interconnect patterns 12 and the second layer interconnect patterns 14, 22 indicates a resin layer for electrically insulating between the second layer interconnect patterns 14 and third layer interconnect patterns 16, and 24 indicates a solder-resist layer for covering a layer formed with the third layer interconnect patterns. The same numbers of these resin layers 18, 20, and 22 are provided at the two surfaces of the core substrate 10.

The semiconductor device substrate of the present embodiment is characterized by using as the material of the core substrate 10 a material having a heat expansion coefficient equivalent to that (close to that) of a semiconductor chip to be mounted on the semiconductor device substrate, that is, a heat expansion coefficient closer to a semiconductor chip than the resin layers and interconnect patterns inside the substrate, using as the materials of the resin layers 18, 20, and 22 epoxy-based resin materials used for the resin layers forming conventional semiconductor device substrate, and using as the material of the resin layers forming the outermost layers of the substrate, that is, the solder-resist layers 24, a resin material with a higher strength and/or a higher elongation than the resin materials used for the other resin layers 18, 20, and 22.

In the semiconductor device substrate of the present embodiment, since a material having a heat expansion coefficient close to the heat expansion coefficient of a semiconductor chip is used for the core substrate 10 and resin materials used for conventional semiconductor device substrate are used for the resin layers 18, 20, and 22, a large thermal stress acts between the core substrate 10 and the resin layers 18, 20, and 22, but by using a resin material provided with a high strength and/or high elongation as the solder-resist layers 24 provided at the outermost layers, the thermal stress occurring between the core substrate 10 and the resin layers 18, 20, and 22 and the interconnect patterns 12, 14, and 16 is kept down and the resin layers and interconnect patterns are prevented from cracking.

As explained above, if using a material close in heat expansion coefficient to a semiconductor chip as the material for the core substrate 10, since a copper material is used for the interconnect patterns 12, 14, and 16, thermal stress will inevitably occur between the core substrate 10 and the interconnect patterns 12, 14, and 16 due to the difference in heat expansion coefficients. Since resin materials used in conventional semiconductor device substrate are used for the resin layers 18, 20, and 22, thermal stress will also occur between the core substrate 10 and the resin layers 18, 20, and 22. As a method for easing these thermal stresses, selection of a material with a high buffering property (material with a high pliability) for the resin layers 18, 20, and 22 is possible, but the semiconductor device substrate of the present embodiment uses a material with a high strength and/or high elongation for only the solder-resist layers 24 provided at the outermost layers so as to prevent the interconnect patterns or resin layers from cracking due to thermal stress generated between the core substrate 10 and the interconnect patterns or resin layers.

In the semiconductor device substrate, a material having a high strength and/or high elongation is used for the outermost solder-resist layers 24 because when using a material close in heat expansion coefficient to a semiconductor device for the core substrate and observing the state of cracking of the semiconductor chip substrate, the cracks are found to start at the edge parts of the interconnects provided at the outermost layers of the substrate or at the open parts at the solder-resist such as the lands and therefore, it may be considered, cracks can be suppressed by making the outermost solder-resist layers 24 high in strength and/or high in elongation.

Table 1 shows the types and characteristics of resin materials used for a semiconductor device substrate having the configuration of FIG. 1 and examined for the state of occurrence of cracks.

TABLE 1

| | | | | | [2] | | | |
|---|---|---|---|---|---|---|---|---|
| | Conventional | Conventional | Conventional | [1] | Polyamid- | [3] | [4] | [5] |
| | resin A | resin B | resin C | Polyimide | imide | PTFE | Aramide | Rubber |
| | Epoxy based | Epoxy based | Epoxy based | based | based | based | based | based |
| Heat expansion | 60 | 60 | 22.5 | 32 | 42 | 65 | 18 | 150 |
| coefficient | | | | | | | | |
| ppm/° C. | | | | | | | | |
| Young's | 2.1 | 3.5 | 7.6 | 4.2 | 2.9 | 1.4 | 7.6 | 0.06 |
| modulus (Gpa) | | | | | | | | |
| Fracture | 43 | 89.9 | 88 | 212 | 124 | 65 | 141 | 19 |
| strength (MPa) | | | | | | | | |
| Elongation (%) | 1.5 | 12.9 | 1.7 | 25 | 68 | 40 | 2.4 | 299 |

Experiments were conducted using the conventionally used epoxy-based resin materials for the resin layers 18, 20, and 22 forming inside layers of the semiconductor device substrate and using five types of resin materials [1] to [5] for the solder-resist layers 24. The experiments showed that when used for the solder-resist layers 24, no cracks occur due to a thermal shock test in the four types of resin materials [1], [2], [3], and [4]. For the rubber-based resin material [5], the heat resistance was low, degradation of the material was observed in the thermal shock test, and the substrate cracked. As shown in Table 1, the resin materials [1] to [4] were higher in both fracture strength and elongation or higher in one of fracture strength and elongation compared with the conventionally used resin materials.

These findings of the experiments mean that by using a material with a high strength and/or high elongation for the outermost resin layers among the resin layers making up a circuit board, it is possible to prevent the substrate from cracking due to thermal stress produced between the core substrate 10 and interconnect patterns 12 and resin layers 18 etc. without using a high strength and/or high elongation resin material for the inside resin layers. In this case, the high strength and/or high elongation solder-resist layers 24 can be considered to act to hold the inside parts of the substrate by covering them from the outside like an eggshell and support them so that thermal stress occurring inside does not appear at the outside.

The heat expansion coefficient of the substrate as a whole becomes 17 to 18 ppm/° C. when using a glass epoxy resin as the core substrate and using an epoxy-based resin for the resin layers, while becomes 9 to 10 ppm/° C. when using a “42 Alloy” iron-nickel alloy as the core substrate and using a polyimide based or polyamidimide based, PTFE based, or aramide based resin material shown in Table 1 for the resin layers, and becomes 6 to 7 ppm/° C. when using a “36 Alloy” iron-nickel alloy as the core substrate.

The members other than the resin ones typically have the following heat expansion coefficients (unit: ppm/° C.):

Semiconductor chip

Si: 3.4 (temperature range of 30 to 400° C.)

GaAs: 6.4 (temperature range of 30 to 400° C.)

Core substrate

“36 Alloy” iron-nickel alloy: 5.7 (temperature range of 30 to 300° C.)

“42 Alloy” iron-nickel alloy: 4.0 to 4.7 (temperature range of 30 to 300° C.)

“50 Alloy” iron-nickel alloy: 9.1 to 10.6 (temperature range of 30 to 300° C.)

Interconnect patterns

Cu: 17.2 ppm (temperature range of 30 to 400° C.)

Note that in the above embodiment, a high strength and/or high elongation resin material was used for only the outermost solder-resist layers 24 of the substrate, but as shown in FIG. 2, it is also effective to use high strength and/or high elongation resin materials rather than the resin materials used for conventional semiconductor device substrates for both of the outermost solder-resist layers 24 and underlying resin layers 22 as shown in FIG. 2. As shown in the present embodiment, when using high strength and/or high elongation resin materials for the outermost solder-resist layers 24 and the underlying resin layers 22, there will be open parts not covered by the resin layers such as the lands 16a at the outermost resin layers of the solder resin layers 24 etc. The edges of these open parts will not be sufficiently held down in some cases.

The solder-resist layers 24 are provided so as to partially overlap the edges of the lands 16a, but when the length (L) of the overlapping parts is not that great due to design considerations, the edges of the lands 16a will not be able to be sufficiently held down by the solder-resist layers 24 in some cases due to manufacturing error etc. In such cases, it would be effective to use a high strength and/or high elongation resin material for the underlying resin layers 22 of the solder-resist layers 24 as well. The underlying resin layers 22 of the solder-resist layers 24 are arranged covering the land 16a parts, so together with the solder-resist layers 24 act to reliably hold the substrate as a whole. In this case as well, it is possible to prevent the substrate from cracking.

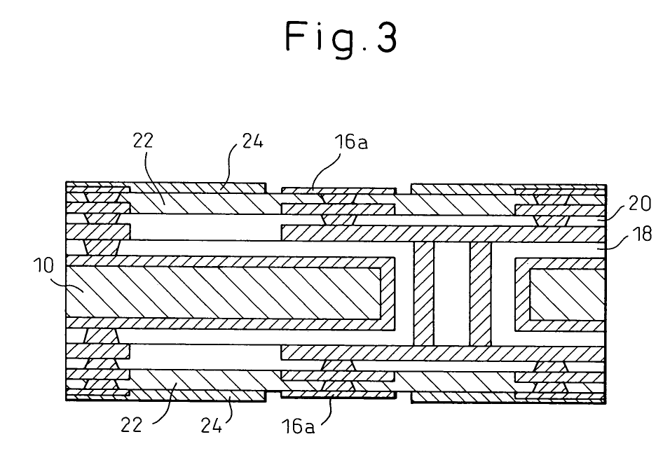

Further, using high strength and/or high elongation resin materials for both the outermost solder-resist layers 24 and the underlying resin layers 22 is effective even when, as shown in FIG. 3, the edges of the lands 16a do not overlap with the solder-resist layers 24 and the lands 16a are exposed completely.

Further, when using a high strength and/or high elongation resin material for the underlying resin layers 22 of the solder-resist layers 24, if the resin layers 22 alone are enough to sufficiently hold down the thermal stress of the substrate, it is also possible not to use the high strength and/or high elongation resin material for the outermost solder-resist layers 24.

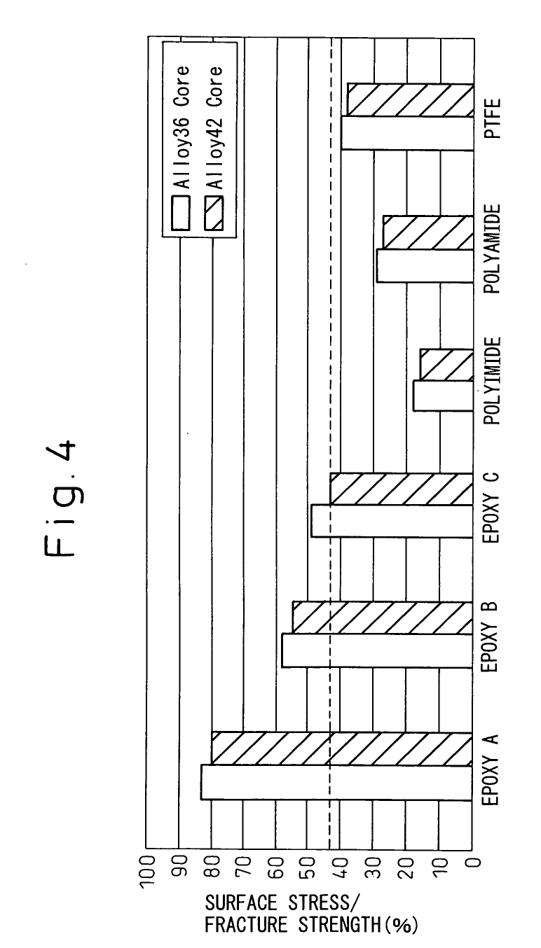

FIG. 4 is a graph of the results of simulation of the relationship between the stress appearing at the outer surface of the substrate and the fracture strength of the resin material in the case of using “36 Alloy” iron-nickel alloy and “42 Alloy” iron-nickel alloy as the core substrate, using resin materials with different fracture strengths for the outermost layers of the semiconductor device substrate, and using conventional resin materials for the inside resin layers and the results of experiments conducted on whether a thermal shock test causes the various substrates to crack. The experiments were conducted for six types of resin materials, that is, the three types of conventional resins shown in Table 1 and polyimide based, polyamidimide based, and PTFE based resins. FIG. 4 shows that cracks occurred for each of the conventional resins A, B, and C, but no cracks occurred in any of the polyimide-based, polyamidimide-based, or PTFE-based resins.

The values shown in the graph are values obtained by dividing the surface stress by the fracture strength of the resin materials. From the graph, it will be understood that the characteristic of the fracture strength of the resin materials is sufficiently correlated with the action of suppression of substrate cracking, that when the fracture strength of the resin material is small, surface stress appears largely and cracks easily occur, and that when the fracture strength of the resin material is large, cracks become hard to occur.

Note that the question of what degree of fracture strength and elongation of the resin material used for the resin layers forming the outermost layer and underlying layers of the semiconductor device substrate would be effective to provide is considered to depend on the contribution of both of the fracture strength and elongation of the resin material on suppressing thermal stress and the properties of the resin materials used for the inside layers of the semiconductor device substrate, the number of layers of interconnect patterns, etc., so it is difficult to limit them to specific values, but from the experimental results and simulation results shown in Table 1, a value of the fracture strength of the resin material of at least 90 MPa and a value of the elongation of at least about 10% are considered as sufficient in practice for suppressing thermal stress occurring in the semiconductor device substrate and preventing cracking.

Note that in the above embodiments, examples of forming the same number of interconnect layers at the two sides of the core substrate were shown. To balance the thermal stress occurring at the two surfaces of the core substrate 10, the general practice is to make the number of interconnect layers formed at the two surfaces of the core substrate 10 the same, but the numbers of interconnect layers formed at the two surfaces of the core substrate 10 do not necessarily have to be made the same. It is also possible to suitably adjust the materials of the resin layers, thicknesses of the interconnect patterns, etc. at the inside layers of the semiconductor device substrate or adjust the properties, thicknesses, etc. of the resin layers provided at the outermost layers so as to adjust the numbers of the interconnect layers provided at the two surfaces of the core substrate 10.

Summarizing the effects of the invention, according to the present invention, as explained above, by using a resin material of a higher strength and/or higher elongation than the resin material used for the inside resin layers for the outermost resin layers of the semiconductor device substrate, it is possible to easily prevent cracks or other trouble in the substrate when using a material with a heat expansion coefficient close to a semiconductor chip for the core substrate, that is, a material having a heat expansion coefficient closer to the semiconductor chip than the resin layers and interconnect patterns inside the substrate. This therefore eliminates the problem of disconnection of interconnect patterns. This has the remarkable effect of enabling the provision of a semiconductor device substrate able to be suitably used for the purpose of mounting a semiconductor chip reduced in strength due to reduction of its dielectric constant.

While the invention has been described with reference to specific embodiments chosen for purpose of illustration, it should be apparent that numerous modifications could be made thereto by those skilled in the art without departing from the basic concept and scope of the invention.

1. A semiconductor device substrate comprised of a core substrate on at least one surface of which interconnect patterns are formed via a resin layer, wherein
the core substrate is formed by a material having a heat expansion coefficient closer to a semiconductor chip than resin layers and the interconnect patterns inside the substrate, and
a resin layer forming an outermost layer of the substrate is formed using a material having at least one of a higher strength and a higher elongation than a resin material used for inner resin layers in the substrate,
thereby cracking, deformation, and other problems arising in the substrate due to the thermal stress occurring between the core substrate and the resin layers in the substrate and interconnect patterns being prevented.

2. A semiconductor device substrate as set forth in claim 1, wherein a resin layer under a resin layer forming an outermost layer of the substrate is made of a resin material having at least one of a higher strength and higher elongation than the resin material of a resin layer used further inside the substrate.

3. A semiconductor device substrate as set forth in claim 1, wherein the resin material having at least one of a higher strength and higher elongation is a resin material having a fracture strength of at least 90 MPa and elongation of at least 10%.

4. A semiconductor device substrate as set forth in claim 2, wherein the resin material having at least one of a higher strength and higher elongation is a resin material having a fracture strength of at least 90 MPa and elongation of at least 10%.
